(19) United States
(12) Patent Application Publication
(10) Pub. No.: US 2016/0143137 A1
(43) Pub. Date: May 19, 2016

(54) PRINTED CIRCUIT BOARD AND METHOD OF MANUFACTURING THE SAME, AND ELECTRONIC COMPONENT MODULE

(71) Applicant: Samsung Electro-Mechanics Co., Ltd., Suwon-Si (KR)

(72) Inventors: Yong Ho BAEK, Suwon-Si (KR); Jung Hyun CHO, Suwon-Si (KR); Young Gwan KO, Suwon-Si (KR); Chang Bae LEE, Suwon-Si (KR)

(73) Assignee: SAMSUNG ELECTRO-MECHANICS CO., LTD., Suwon-Si (KR)

(21) Appl. No.: 14/878,496

(22) Filed: Oct. 8, 2015

(30) Foreign Application Priority Data
Nov. 17, 2014 (KR) 10-2014-0160019
Mar. 3, 2015 (KR) 10-2015-0029994

(51) Int. Cl. H05K 1/11; H05K 3/46; H05K 3/10; H05K 1/02; H05K 1/18

(52) U.S. Cl. CPC H05K 1/11; H05K 1/111; H05K 1/0298; H05K 1/0274; H05K 1/181; H05K 3/10; H05K 3/46; H05K 1/115; H05K 3/4644

(57) ABSTRACT

There are provided a printed circuit board, a method of manufacturing the same, and an electronic component module. The printed circuit board comprises a first circuit layer; a first insulating layer formed to cover a portion or all of the first circuit layer; a second circuit layer formed on the first insulating layer; a second insulating layer formed on an overall surface of the board so as to cover the first circuit layer and the second circuit layer; and a third circuit layer formed in the second insulating layer. The second circuit layer has a circuit pattern of a fine pitch as compared to the first circuit layer and the third circuit layer.

### CROSS-REFERENCE TO RELATED APPLICATION

This application claims the benefit of Korean Patent Application Nos. 10-2014-0160019 and 10-2015-0029994, filed on Nov. 17, 2014 and Mar. 3, 2015, entitled “Printed Circuit Board and Method of Manufacturing the Same, and Electronic Component Module” which are hereby incorporated by reference in their entireties into this application.

### BACKGROUND

The present disclosure relates to a printed circuit board, a method of manufacturing the same, and an electronic component module.

Functions required for a smartphone and a tablet have increased, and an expected operation time for a battery has correspondingly increased. Since there is still a limit in a battery technology, a volume of the battery needs to be increased in order to increase capacity of the battery. Therefore, sizes of parts except for the battery have been thinned and miniaturized.

### RELATED ART DOCUMENT

### Patent Document

(Patent Document 1) U.S. Patent Application Publication No. 2014-0268612

### SUMMARY

An aspect of the present disclosure may provide a printed circuit board capable of implementing a die to die interconnection through a fine circuit which is locally formed on an insulating layer, and a method of manufacturing the same.

An aspect of the present disclosure may also provide a printed circuit board capable of improving reliability of a die to die interconnection structure, and a method of manufacturing the same.

An aspect of the present disclosure may also provide an electronic component module to which the printed circuit board is applied.

According to an aspect of the present disclosure, a printed circuit board may include: a first circuit layer; a first insulating layer formed to cover a portion or all of the first circuit layer; a second circuit layer formed on the first insulating layer; a second insulating layer formed on an overall surface of the board so as to cover the first circuit layer and the second circuit layer; and a third circuit layer formed in the second insulating layer, wherein the second circuit layer has a circuit pattern of a fine pitch as compared to the first circuit layer and the third circuit layer.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view illustrating a printed circuit board according to an exemplary embodiment of the present disclosure;

FIG. 2 is a cross-sectional view illustrating a printed circuit board according to another exemplary embodiment of the present disclosure;

FIG. 3 is a cross-sectional view illustrating a printed circuit board according to still another exemplary embodiment of the present disclosure;

FIG. 4 is a cross-sectional view illustrating a printed circuit board according to still another exemplary embodiment of the present disclosure

FIG. 5 is a cross-sectional view illustrating a printed circuit board according to still another exemplary embodiment of the present disclosure;

FIG. 6 is a cross-sectional view illustrating a printed circuit board according to still another exemplary embodiment of the present disclosure;

FIG. 7 is a cross-sectional view illustrating a printed circuit board according to still another exemplary embodiment of the present disclosure;

FIG. 8 is a cross-sectional view illustrating an electronic component module according to an exemplary embodiment of the present disclosure;

FIG. 9 is a flow chart illustrating a method of manufacturing a printed circuit board according to an exemplary embodiment of the present disclosure; and

FIGS. 10 to 22 are process cross-sectional views illustrating the method of manufacturing a printed circuit board according to an exemplary embodiment of the present disclosure in a process sequence.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

Printed Circuit Board

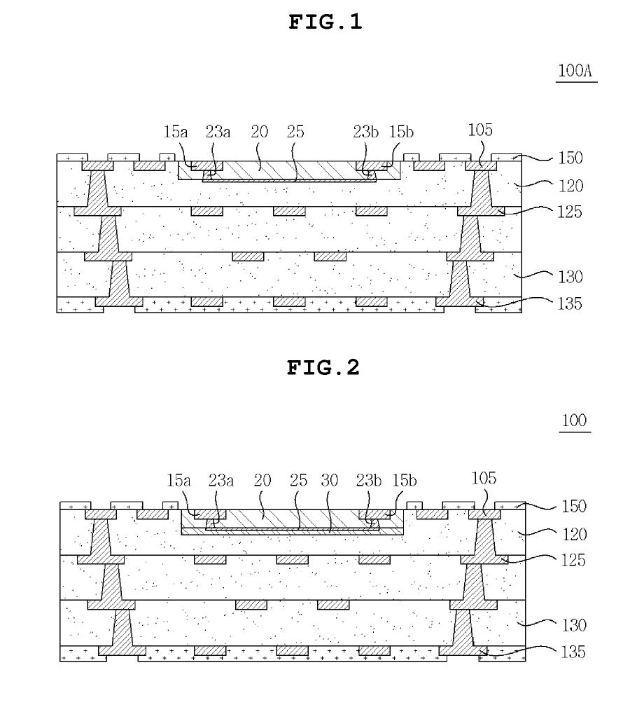

FIG. 1 is a cross-sectional view illustrating a printed circuit board according to an exemplary embodiment of the present disclosure.

Referring to FIG. 1, a printed circuit board 100A includes a first circuit layer 101, a first insulating layer 20 formed to cover a portion of the first circuit layer 101, a second circuit layer 25 formed on the first insulating layer 20, a second insulating layer 120 formed on an overall surface of the board so as to cover the first circuit layer 101 and the second circuit layer 25, and a third circuit layer 125 formed in the second insulating layer 120.

Here, the second circuit layer 25 has a circuit pattern of a fine pitch as compared to the first circuit layer 101 and the third circuit layer 125.

The first circuit layer 101 is formed to be buried in upper surfaces of the first insulating layer 20 and the second insulating layer 120.

The first circuit layer 101 also includes pads 15a, 15b, and 105 for mounting a plurality of electronic components.

The second circuit layer 25 includes connection patterns functioning as signal lines connecting the plurality of electronic components.

The connection patterns are implemented with a fine pitch as compared to the circuit patterns formed in the first circuit layer 101 and the third circuit layer 125. For example, the connection patterns may be formed to have a pitch (line/space) of 1 μm/1 μm to 5 μm/5 μm. Here, the line means a width of a pattern, and the space means an interval between the patterns.

The second circuit layer 25 may be surface-treated by a plasma process in order to improve adhesion with the second insulating layer 120 later.

The first circuit layer 101 and the second circuit layer 25 are electrically connected through a plurality of micro vias 23a and 23b.

The micro vias 23a and 23b, which are fine vias, may be formed, for example, to have a diameter of 5 to 35 μm. By implementing the micro vias 23a and 23b as the fine vias, a degree of freedom of a wiring process of the second circuit layer 25 may be increased.

As the first insulating layer 20, a photosensitive resin layer having lower surface roughness than that of a typical material of a resin insulating layer may be used to easily form a fine circuit. As the first insulating layers 20, for example, the photosensitive resin layer that does not contain a glass sheet may be used.

Here, the first insulating layer 20 is formed to be buried in the second insulating layer 120 so that an upper surface of the first insulating layer 20 is exposed.

Meanwhile, a plurality of build-up layers including a build-up insulating layer 130 and a build-up circuit layer 135 may be formed on the third circuit layer 125.

Here, interlayer circuit layers are electrically connected to each other by a typical connection via.

In addition, although not shown, a through via may also be formed.

Meanwhile, as a material of the circuit layer including the via, any material may be used without being limited as long as it is used as a circuit conductive material in a field of printed circuit board. For example, the circuit layer may be formed of copper (Cu).

As the second insulating layer 120 and the build-up insulating layer 130, the resin insulating layer formed of material different from that of the first insulating layer 20 may be used.

A material of the second insulating layer 120 and the build-up insulating layer 130 is not particularly limited as long as it is typically used as an insulating material in the printed circuit board.

According to the present exemplary embodiment, as the material of the insulating layers 120 and 130, a thermosetting resin such as an epoxy resin and a thermoplastic resin such as polyimide as the resin used for a typical coreless substrate may be used, but the material of the insulating layers 120 and 130 is not particularly limited thereto. For example, the insulating layers 120 and 130 may be formed of Ajinomoto Build up Film (ABF), and a resin such as FR-4, Bismaleimide Triazine (BT), or the like.

Selectively, as a protection layer exposing the plurality of pads, a typical liquid or film type of solder resist layer 150 may be formed on the outermost layer. In addition, the solder resist layer may be omitted on the first insulating layer 20, if necessary.

The solder resist layer, which is formed to protect the circuit pattern of the outermost layer and perform an electrical insulation, has an opening formed to expose the pad of the outermost layer connected to an external product.

In addition, a surface treatment layer may be selectively and additionally formed on the pad exposed through the opening of the solder resist layer.

The surface treatment layer is not particularly limited as long as it is known in the art and may be formed, for example, by electro gold plating, immersion gold plating, organic solderability preservative (OSP) or immersion tin plating, immersion silver plating, direct immersion gold (DIG) plating, hot air solder leveling (HASL), or the like.

The pad formed by the above-mentioned process may be used as a wire-bonding pad or a bump pad depending on an application object, or may be used as a solder ball pad for mounting an external connection terminal such as a solder ball.

According to the present exemplary embodiment, a fine circuit structure including an ultrafine circuit and a small via may be locally implemented on the board.

Further, by implementing the circuit layer of the outermost layer in a buried pattern, a high density fine circuit may be implemented.

FIG. 2 is a cross-sectional view illustrating a printed circuit board according to another exemplary embodiment of the present disclosure and a description of overlapped configurations will be omitted.

Referring to FIG. 2, a printed circuit board 100 includes the first circuit layer 101, the first insulating layer 20 formed to cover a portion of the first circuit layer 101, the second circuit layer 25 formed on the first insulating layer 20, the second insulating layer 120 formed on the overall surface of the board so as to cover the first circuit layer 101 and the second circuit layer 25, and the third circuit layer 125 formed in the second insulating layer 120.

The plurality of build-up layers including the build-up insulating layer 130 and the build-up circuit layer 135 are formed on the third circuit layer 125.

Here, the second circuit layer 25 has the circuit pattern of the fine pitch as compared to the first circuit layer 101 and the third circuit layer 125.

A first protection layer 30 covering the second circuit layer 25 is formed on a lower surface of the first insulating layer 20.

The first protection layer 30 is locally formed on the second circuit layer 25 implemented in the fine circuit to serve as the protection layer preventing damage of the fine circuit.

As the first insulating layer 20 and the first protection layer 30, the photosensitive resin layer having lower surface roughness than that of the typical material of the resin insulating layer may be used to easily form and locally apply the fine circuit. As the first insulating layers 20 and the first protection layer 30, for example, the photosensitive resin layer that does not contain the glass sheet may be used.

According to the present exemplary embodiment, the fine circuit structure including the ultrafine circuit and the small via may be locally implemented on the board.

In addition, by implementing the circuit layer of the outermost layer in the buried pattern, the high density fine circuit may be implemented.

Further, by forming the protection layer locally covering the second circuit layer, the fine circuit may be protected without being damaged.

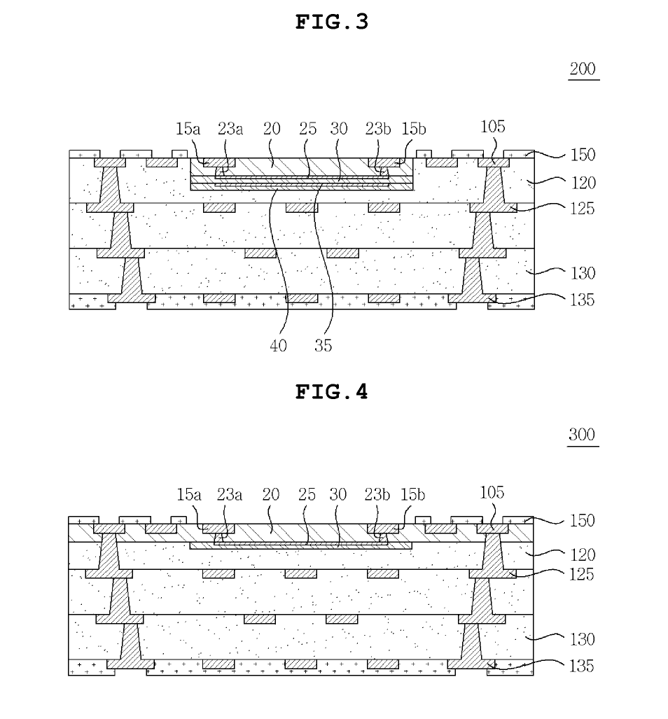

FIG. 3 is a cross-sectional view illustrating a printed circuit board according to still another exemplary embodiment of the present disclosure and a description of overlapped configurations will be omitted.

Referring to FIG. 3, a printed circuit board 200 includes a first circuit layer 101, a first insulating layer 20 formed to cover a portion of the first circuit layer 101, a second circuit layer 25 formed on the first insulating layer 20, a second insulating layer 120 formed on a front surface of the board so as to cover the first circuit layer 101 and the second circuit layer 25, and a third circuit layer 125 formed in the second insulating layer 120.

The plurality of build-up layers including the build-up insulating layer 130 and the build-up circuit layer 135 may be formed on the third circuit layer 125.

Here, the second circuit layer 25 has the circuit pattern of the fine pitch as compared to the first circuit layer 101 and the third circuit layer 125.

The first protection layer 30 covering the second circuit layer 25, a wiring layer 35, and a second protection layer 40 are sequentially formed on the lower surface of the first insulating layer 20.

The wiring layer 35, which is a fine circuit for a wide input/output (I/O) action, may be implemented as one or more multiple layers between the first circuit layer 101 and the third circuit layer 125.

The wiring layer 35 is formed to have a fine pitch as compared to the first circuit layer 101 and the third circuit layer 125.

For example, the wiring layer 35 may be formed to have a pitch of 1 μm/1 μm to 5 μm/5 μm.

The wiring layer 35 may be surface-treated by a plasma process in order to improve adhesion with the second protection layer 40 later.

The second protection layer 40 serves as the protection layer for protecting the wiring layer 35.

The protection layers 30 and 40 are locally formed on the fine circuit to serve as the protection layer preventing damage of the fine circuit.

As the first insulating layer 20 and the protection layers 30 and 40, the photosensitive resin layer having lower surface roughness than that of the typical material of the resin insulating layer may be used to easily form and locally apply the fine circuit. As the first insulating layers 20 and the protection layers 30 and 40, for example, the photosensitive resin layer that does not contain the glass sheet may be used.

According to the present exemplary embodiment, the fine circuit structure including the ultrafine circuit and the small via may be locally implemented on the board.

In addition, by implementing the circuit layer of the outermost layer in the buried pattern, the high density fine circuit may be implemented.

In addition, by implementing one or more fine patterns between the first circuit layer and the third circuit layer, the wide I/O action may be implemented.

Further, by forming the protection layers locally covering the fine circuit, the fine circuit may be protected without being damaged.

FIG. 4 is a cross-sectional view illustrating a printed circuit board according to still another exemplary embodiment of the present disclosure and a description of overlapped configurations will be omitted.

Referring to FIG. 4, a printed circuit board 300 includes the first circuit layer 101, the first insulating layer 20 formed to cover the first circuit layer 101, the second circuit layer 25 formed on the first insulating layer 20, the second insulating layer 120 formed on the overall surface of the board so as to cover the second circuit layer 25, and the third circuit layer 125 formed in the second insulating layer 120.

The plurality of build-up layers including the build-up insulating layer 130 and the build-up circuit layer 135 may be formed on the third circuit layer 125.

Here, the second circuit layer 25 has the circuit pattern of the fine pitch as compared to the first circuit layer 101 and the third circuit layer 125.

The first protection layer 30 locally covering the second circuit layer 25 is formed on a lower surface of the first insulating layer 20.

According to the present exemplary embodiment, the second insulating layer 120 is formed on the entire lower surface of the first insulating layer 20, such that workability may be improved and occurrence possibility of voids and residues is reduced, thereby making it possible to secure reliability of the product.

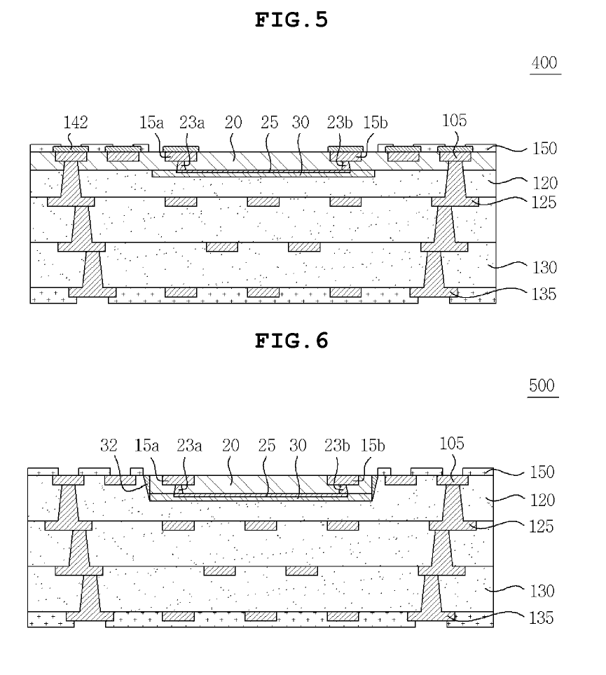

FIG. 5 is a cross-sectional view illustrating a printed circuit board according to still another exemplary embodiment of the present disclosure and a description of overlapped configurations will be omitted.

Referring to FIG. 5, a printed circuit board 400 includes the first circuit layer 101, the first insulating layer 20 formed to cover the first circuit layer 101, the second circuit layer 25 formed on the first insulating layer 20, the second insulating layer 120 formed on the overall surface of the board so as to cover the second circuit layer 25, and the third circuit layer 125 formed in the second insulating layer 120.

The plurality of build-up layers including the build-up insulating layer 130 and the build-up circuit layer 135 may be formed on the third circuit layer 125.

Here, the second circuit layer 25 has the circuit pattern of the fine pitch as compared to the first circuit layer 101 and the third circuit layer 125.

The first protection layer 30 locally covering the second circuit layer 25 is formed on a lower surface of the first insulating layer 20.

The first circuit layer 101 is formed to be buried in an upper surface of the first insulating layer 20.

The first circuit layer 101 also includes pads 15a, 15b, and 105 for mounting a plurality of electronic components.

Metal posts 142 are formed on the pads 15a, 15b, and 105.

According to the present exemplary embodiment, a fine bump pitch action may be implemented by forming protruded metal posts on buried pads.

FIG. 6 is a cross-sectional view illustrating a printed circuit board according to still another exemplary embodiment of the present disclosure.

Referring to FIG. 6, a printed circuit board 500 includes a first circuit layer 101, a first insulating layer 20 formed to cover a portion of the first circuit layer 101, a second circuit layer 25 formed on the first insulating layer 20, a second insulating layer 120 formed on an overall surface of the board so as to cover the first circuit layer 101 and the second circuit layer 25, and a third circuit layer 125 formed in the second insulating layer 120.

The plurality of build-up layers including the build-up insulating layer 130 and the build-up circuit layer 135 may be formed on the third circuit layer 125.

The first protection layer 30 covering the second circuit layer 25 is formed on a lower surface of the first insulating layer 20.

Here, the first insulating layer 20 has tapered parts 32 formed on both sides forming boundaries with the second insulating layer 120.

The tapered parts 32 are formed between the insulating layers made of different materials, and in the case in which the first protection layer 30 made of the material different from that of the second insulating layer 120 is applied, the tapered parts 32 may also be formed on both sides of the first protection layer 30 forming the boundaries with the second insulating layer 120 as well as both sides of the first insulating layer 20.

According to the present exemplary embodiment, the tapered parts having a gradual descent shape are formed on both sides of the first insulating layer, such that the first insulating layer has a wetting angle.

Since the wetting angle implemented as described above serves as a delay time function upon transferring stress due to a mismatch between different materials which may occur on an interface between the first insulating layer and the second insulating layer made of the different materials, delamination by moisture absorption, and cracks, the wetting angle contributes to improve reliability of the different materials.

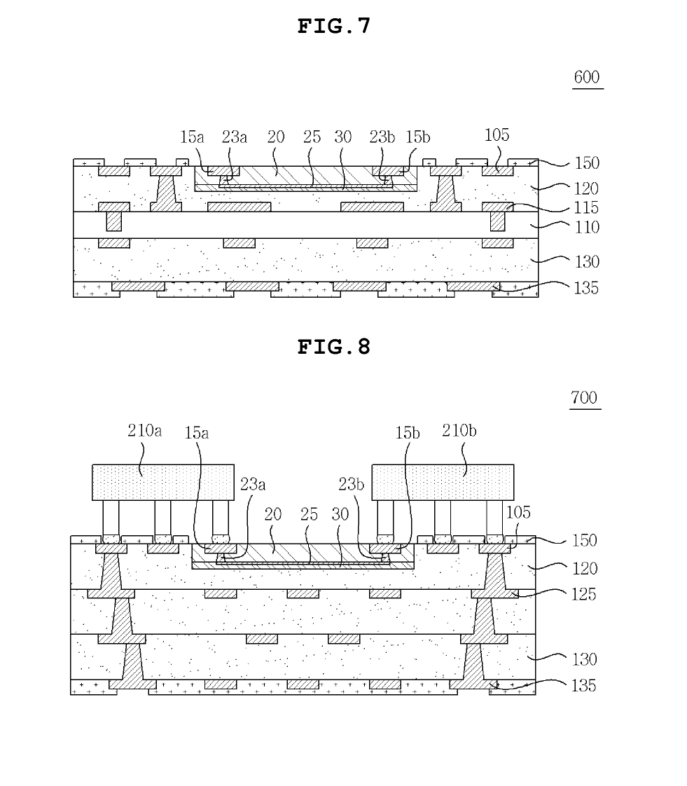

FIG. 7 is a cross-sectional view illustrating a printed circuit board according to still another exemplary embodiment of the present disclosure and a description of overlapped configurations will be omitted.

Referring to FIG. 7, a printed circuit board 600 includes a first circuit layer 101, a first insulating layer 20 formed to cover a portion of the first circuit layer 101, a second circuit layer 25 formed on the first insulating layer 20, a second insulating layer 120 formed on an overall surface of the board so as to cover the first circuit layer 101 and the second circuit layer 25, and a third circuit layer 125 formed in the second insulating layer 120.

A core insulating layer 110 and the build-up insulating layer 130 may be sequentially disposed on the lower surface of the second insulating layer 120.

A material of the core insulating layer 110 is not particularly limited as long as it is an insulating resin which is typically used as an insulating material of a core substrate in the printed circuit board, and a thermosetting resin such as an epoxy resin, a thermoplastic resin such as polyimide, or a resin in which a reinforcing material such as glass fiber or an inorganic filler is impregnated in the above-mentioned resin, for example, a prepreg may be used.

The circuit layers 115 and 125 are each formed on both surfaces of the core insulating layer 110, and as a result, the third circuit layer 125 is buried in the lower surface of the second insulating layer 120.

According to the present exemplary embodiment, the fine circuit structure including the ultrafine circuit and the small via may be locally implemented on a typical core substrate, in addition to a thin plate structure such as coreless.

Electronic Component Module

FIG. 8 is a cross-sectional view illustrating an electronic component module according to an exemplary embodiment of the present disclosure and a description of overlapped configurations will be omitted.

Referring to FIG. 8, an electronic component module 700 includes a plurality of electronic components 210a and 210b mounted on the printed circuit board 100.

The printed circuit board 100 includes the first circuit layer 101, the first insulating layer 20 formed to cover a portion of the first circuit layer 101, the second circuit layer 25 formed on the first insulating layer 20, the second insulating layer 120 formed on the overall surface of the board so as to cover the first circuit layer 101 and the second circuit layer 25, and the third circuit layer 125 formed in the second insulating layer 120.

The plurality of build-up layers including the build-up insulating layer 130 and the build-up circuit layer 135 may be formed on the third circuit layer 125.

The first protection layer 30 covering the second circuit layer 25 is formed on a lower surface of the first insulating layer 20.

Here, the second circuit layer 25 has the circuit pattern of the fine pitch as compared to the first circuit layer 101 and the third circuit layer 125.

The first circuit layer 101 is formed to be buried in upper surfaces of the first insulating layer 20 and the second insulating layer 120.

The first circuit layer 101 also includes the pads 15a, 15b, and 105 for mounting the plurality of electronic components 210a and 210b.

The second circuit layer 25 includes connection patterns functioning as signal lines connecting the plurality of electronic components 210a and 210b.

The connection patterns are implemented with a fine pitch as compared to the circuit patterns formed in the first circuit layer 101 and the third circuit layer 125. For example, the connection patterns may be formed to have a pitch of 1 μm/1 μm to 5 μm/5 μm.

In addition, the first circuit layer 101 and the second circuit layer 25 are electrically connected through the plurality of micro vias 23a and 23b.

The micro vias 23a and 23b, which are fine vias, may be formed, for example, to have a diameter of 5 to 35 μm. By implementing the micro vias 23a and 23b as the fine vias, a degree of freedom of a wiring process of the second circuit layer 25 may be increased.

The electronic components 210a and 210b are connected to the pads 15a, 15b, and 105 to be mounted on the printed circuit board 100.

The pads 15a, 15b, and 105 of the first circuit layer 101 are electrically connected to the connection patterns of the second circuit layer 25 through the micro vias 23a and 23b.

The connection patterns of the second circuit layer 25 function as the signal lines connecting the plurality of electronic components 210a and 210b.

The electronic components 210a and 210b include various electronic elements such as a passive element and an active element and any electronic elements may be applied without being limited as long as it may be typically mounted on the printed circuit board or be embedded in the printed circuit board. Although not shown, a semiconductor package may also be mounted on the printed circuit board.

According to the present exemplary embodiment, a die to die interconnection within the board may be performed by locally implementing the fine circuit structure including the ultrafine circuit and the small via on the board.

In addition, by implementing the circuit layer of the outermost layer in the buried pattern, the high density fine circuit may be implemented.

Further, by locally forming the protection layer covering the second circuit layer, the fine circuit may be protected without being damaged.

Method of Manufacturing Printed Circuit Board

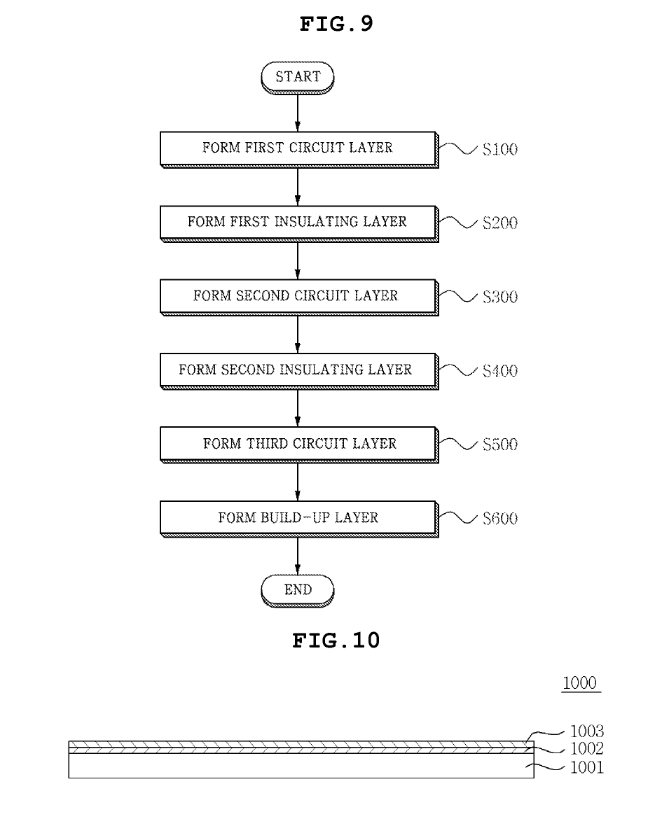

FIG. 9 is a flow chart illustrating a method of manufacturing a printed circuit board according to an exemplary embodiment of the present disclosure and FIGS. 10 to 22 are process cross-sectional views illustrating the method of manufacturing a printed circuit board according to an exemplary embodiment of the present disclosure in a process sequence.

Referring to FIG. 9, the method of manufacturing the printed circuit board includes an operation (S100) of forming a first circuit layer, an operation (S200) of forming a first insulating layer, an operation (S300) of forming a second circuit layer, an operation (S400) of forming a second insulating layer, an operation (S500) of forming a third circuit layer, and an operation (S600) of forming a build-up layer.

Hereinafter, the respective processes will be described with reference to the process cross-sectional views illustrated in FIGS. 10 to 22.

First, referring to FIG. 10, a carrier member 1000 is prepared.

The carrier member 1000 includes a carrier core 1001, and a first metal layer 1002 and a second metal layer 1003 which are sequentially formed on one surface or both surfaces of the carrier core 1001.

The carrier core 1001, which is to support an insulating layer and/or a circuit layer at the time of forming the insulating layer and/or the circuit layer, may be formed of an insulating material or a metallic material.

The first metal layer 1002 may be formed of copper, but is not particularly limited thereto.

The second metal layer 1003 may serve as a seed layer and may be formed of copper.

However, the carrier member described above merely illustrates one case, and the carrier member 1000 may be used in the present disclosure without being particularly limited as long as it is used as a support substrate in a field of circuit board and may be detached or removed later.

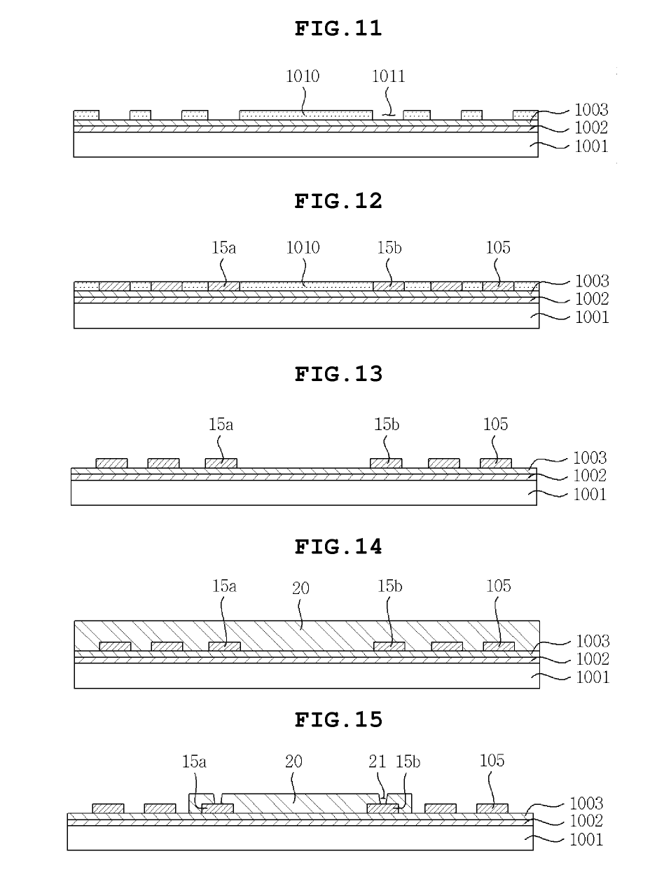

Next, referring to FIG. 11, a resist pattern 1010 having a predetermined opening 1011 is formed on the carrier member.

Specifically, after a liquid plating resist is coated on the carrier member, the opening 1011 for forming the circuit pattern is formed by a typical exposure and development process.

In the case in which the plating resist is coated in a liquid form, since uniformity of a thickness is high, a fine circuit structure may be easily formed later.

Next, referring to FIG. 12, a first circuit layer 101 including a plurality of pads 15a, 15b, and 105 is formed by filling a plated layer in the opening 1011 by a plating process.

The plating process may be performed by an electroless plating, an electroplating, or a combination thereof, and may be performed by a copper plating.

Next, referring to FIG. 13, the resist pattern 1010 is removed.

Next, referring to FIG. 14, a first insulating layer 20 is formed on the carrier member so as to cover the first circuit layer 101.

As the first insulating layer 20, a photosensitive resin layer having lower surface roughness than that of a typical material of a resin insulating layer may be used to easily form the fine circuit.

Next, referring to FIG. 15, the first insulating layer 20 is patterned so as to cover a portion of the first circuit layer 101, for example, the pads 15a and 15b, and a micro via hole 21 is formed.

The patterning process and the process of forming the micro via hole 21 may be performed by a photolithography method including the exposure and development process.

The micro via hole 21 may also be formed by laser machining.

The micro via hole 21 may be formed, for example, to have a diameter of about 5 to 35 μm.

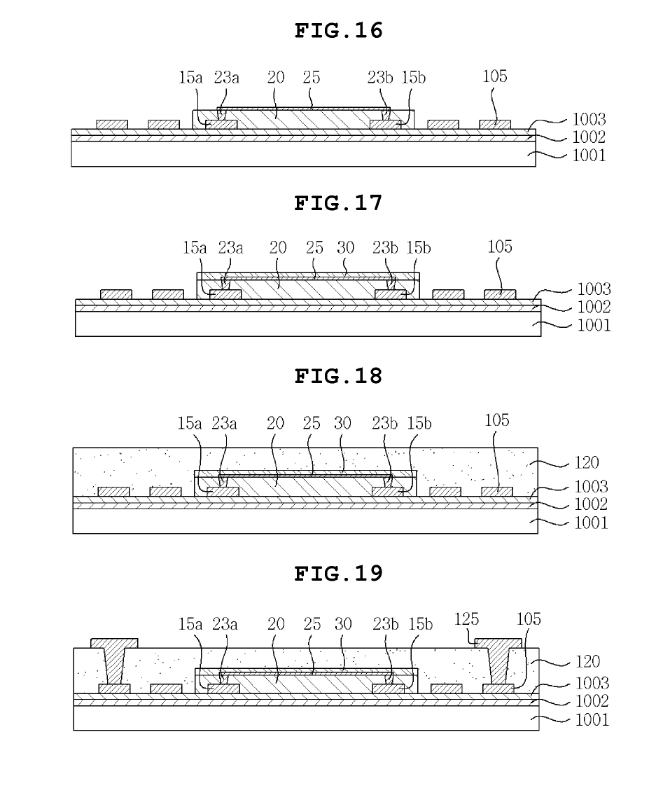

Next, referring to FIG. 16, the fine circuit structure including a plurality of micro vias 23a and 23b and a second circuit layer 25, which is the fine circuit, is formed in the first insulating layer 20 by the plating process.

The plating process may be performed by an electroless plating, an electroplating, or a combination thereof, and may be performed by copper plating.

By the processes described above, the pads 15a and 15b of the first circuit pattern 101 and the second circuit layer 25 are electrically connected to each other by the micro vias 23a and 23b.

The second circuit layer 25 includes connection patterns for connecting a plurality of electronic components, and the connection patterns function as signal lines connecting the plurality of electronic components.

Additionally, a plasma surface treatment may be performed for the second circuit layer in order to increase adhesion with the insulating layer later.

Next, referring to FIG. 17, a first protection layer 30 for preventing damage of the second circuit layer 25 is locally formed on the first insulating layer 20 so as to cover the second circuit layer 25.

As the first protection layer 30, a photosensitive resin layer having lower surface roughness than that of a typical material of a resin insulating layer may be used to easily form the fine circuit structure.

Next, referring to FIG. 18, a second insulating layer 120 is formed on an overall surface of the carrier member so as to cover the first circuit layer 101 and the second circuit layer 25.

Here, the second insulating layer 120 is formed of a resin layer different from that of the first insulating layer 20 and the first protection layer 30.

A material of the second insulating layer 120 is not particularly limited as long as it is typically used as an insulating material in the printed circuit board.

According to the present exemplary embodiment, as the material of the second insulating layer 120, a thermosetting resin such as an epoxy resin and a thermoplastic resin such as polyimide as the resin used for a typical coreless substrate may be used, but the material of the second insulating layer 120 is not particularly limited thereto. For example, the second insulating layer 120 may be formed of Ajinomoto Build up Film (ABF), and a resin such as FR-4, Bismaleimide Triazine (BT), or the like.

Next, referring to FIG. 19, a third circuit layer 125 including a via is formed in the second insulating layer 120.

The third circuit layer 125 may be formed by a laser process and a semi additive process (SAP) depending on a typical method of forming the circuit pattern.

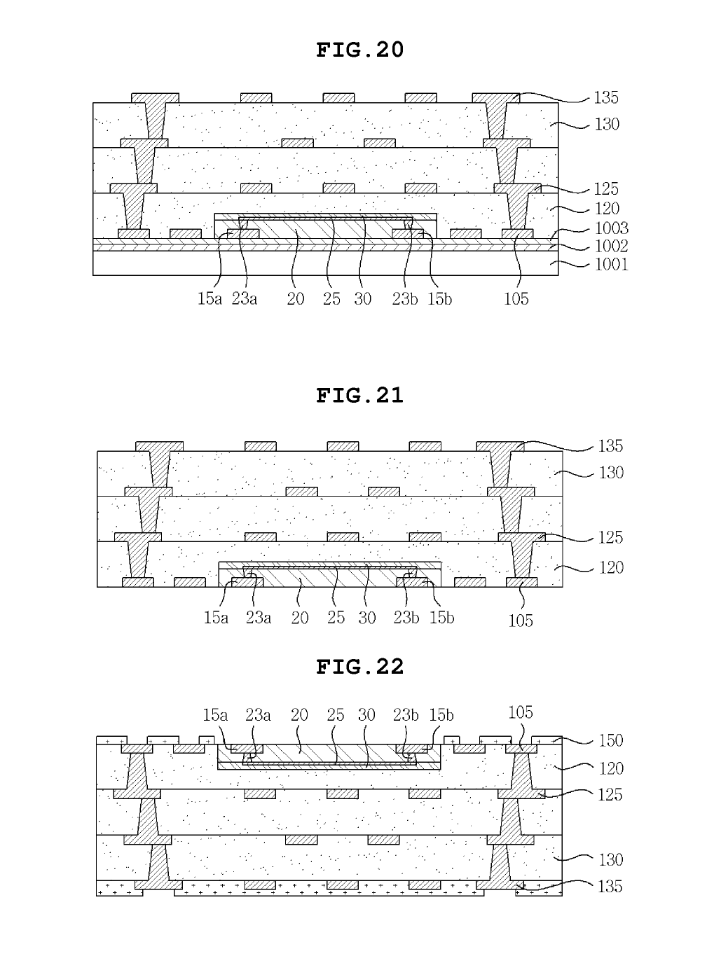

Next, referring to FIG. 20, build-up layers are formed as many as the desired number of layers by stacking a build-up insulating layer 130 and repeating a typical process of forming a build-up circuit layer 135 such as the laser process and the SAP.

The build-up insulating layer 130 is formed of a material different from that of the first insulating layer 20.

The build-up insulating layer 130 may be formed of the same material as that of the second insulating layer 120, which is an insulating resin which is typically used as an insulating material in the printed circuit board.

Next, referring to FIG. 21, the carrier member is removed.

A process of removing the carrier member may be performed by a process of removing the second metal layer 1003 after the carrier core 1001 and the first metal layer 1002 are detached from each other.

The process of removing the carrier member is not particularly limited, and may be performed by various methods depending on a configuration of the carrier member which is actually used.

Next, referring to FIG. 22, a typical liquid or film type of solder resist layer 150, which is the protection layer exposing the plurality of pads 15a, 15b, and 105, is formed on the outermost layer.

The solder resist layer, which is formed to protect the circuit pattern of the outermost layer and perform an electrical insulation, has an opening formed to expose the pad of the outermost layer connected to an external product.

In addition, a surface treatment layer may be selectively and additionally formed on the pad exposed through the opening of the solder resist layer.

According to the present exemplary embodiment, the first circuit layer including the pad of a surface on which the electronic component is mounted is implemented in a buried pattern and the fine circuit structure is applied to the insulating layer of the outermost layer, thereby making it possible to form the die to die interconnection within the printed circuit board by the fine pattern.

Further, by locally forming the protection layers for protecting the fine circuit, the fine circuit may be protected without being damaged.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A printed circuit board comprising:
a first circuit layer;
a first insulating layer formed to cover a portion or all of the first circuit layer;
a second circuit layer formed on the first insulating layer;
a second insulating layer formed on an overall surface of the board so as to cover the first circuit layer and the second circuit layer; and
a third circuit layer formed in the second insulating layer,
wherein the second circuit layer has a circuit pattern of a fine pitch as compared to the first circuit layer and the third circuit layer.

2. The printed circuit board of claim 1, wherein the first circuit layer is formed to be buried in the first insulating layer and the second insulating layer, or an upper surface of the first insulating layer.

3. The printed circuit board of claim 1, wherein the first circuit layer includes pads for mounting a plurality of electronic components.

4. The printed circuit board of claim 3, further comprising metal posts formed on the pads.

5. The printed circuit board of claim 1, wherein the second circuit layer has connection patterns for connecting a plurality of electronic components.

6. The printed circuit board of claim 1, further comprising a micro via electrically connecting the first circuit layer and the second circuit layer.

7. The printed circuit board of claim 1, wherein the third circuit layer is formed to be buried in a lower surface of the second insulating layer.

8. The printed circuit board of claim 1, wherein the first insulating layer and the second insulating layer are formed of different resin insulating layers.

9. The printed circuit board of claim 1, wherein the first insulating layer is a photosensitive resin layer.

10. The printed circuit board of claim 1, further comprising a protection layer formed on a lower surface of the first insulating layer so as to cover the second circuit layer.

11. The printed circuit board of claim 1, further comprising a first protection layer formed on a lower surface of the first insulating layer so as to cover the second circuit layer, and a wiring layer formed on a lower surface of the first protection layer.

12. The printed circuit board of claim 11, wherein the wiring layer has a circuit pattern of a fine pitch as compared to the first circuit layer and the third circuit layer.

13. The printed circuit board of claim 1, wherein the first insulating layer has tapered parts formed on both sides forming boundaries with the second insulating layer.

14. The printed circuit board of claim 1, further comprising a build-up layer including a build-up insulating layer and a build-up circuit layer, which are formed on the third circuit layer.

15. An electronic component module comprising:
a printed circuit board including a first circuit layer, a first insulating layer formed to cover a portion or all of the first circuit layer, a second circuit layer formed on the first insulating layer, a second insulating layer formed on an overall surface of the board so as to cover the first circuit layer and the second circuit layer, and a third circuit layer formed in the second insulating layer; and
an electronic component mounted on the printed circuit board,
wherein the second circuit layer has a circuit pattern of a fine pitch as compared to the first circuit layer and the third circuit layer.

16. The electronic component module of claim 15, wherein the first circuit layer is formed to be buried in the first insulating layer and the second insulating layer, or an upper surface of the first insulating layer.

17. The electronic component module of claim 15, wherein the first circuit layer includes pads for mounting a plurality of electronic components.

18. The electronic component module of claim 15, wherein the second circuit layer has connection patterns for connecting a plurality of electronic components.

19. The electronic component module of claim 15, wherein the first insulating layer is a photosensitive resin layer.

20. A method of manufacturing a printed circuit board, the method comprising:
forming a first circuit layer;
forming a first insulating layer so as to cover a portion or all of the first circuit layer;
forming a second circuit layer on the first insulating layer;
forming a second insulating layer on an overall surface of the board so as to cover the first circuit layer and the second circuit layer; and
forming a third circuit layer in the second insulating layer,
wherein the second circuit layer has a circuit pattern of a fine pitch as compared to the first circuit layer and the third circuit layer.
